(19) United States
(12) Patent Application Publication
(10) Pub. No.: US 2026/0147282 A1
(43) Pub. Date: May 28, 2026

(54) Feature Transformer Architecture For Advanced Semiconductor Metrology

(71) Applicant: KLA Corporation, Milpitas, CA (US)

(72) Inventors: Zhengquan Tan, Cupertino, CA (US); Min-Yeong Moon, Ann Arbor, MI (US); Pavan Gurudath, Ann Arbor, MI (US); Stilian Ivanov Pandev, Santa Clara, CA (US)

(21) Appl. No.: 19/323,211

(22) Filed: Sep. 9, 2025

Related U.S. Application Data
(60) Provisional application No. 63/711,717, filed on Oct. 25, 2024.

(51) Int. Cl. G03F 7/00

(52) U.S. Cl. CPC G03F 7/70625; G03F 7/705; G03F 7/706841

(57) ABSTRACT

Methods and systems for measurements of complex semiconductor structures employing measurement signal combinations derived from optical, x-ray, or electron based measurements of the structure of interest are described herein. The derived measurement signal combinations highlight signal features that exhibit enhanced sensitivity to one or more parameters of interest characterizing the semiconductor structure under measurement. In one aspect, one or more measurement signal combinations are analytically derived by operation of a mathematical function or combination of multiple mathematical functions on measurement signals. In another aspect, one or more measurement signal combinations are derived by operation of a Measurement Signal Object (MSO) model on measurement signals. An MSO model is determined using a transformer architecture employing an attention mechanism operating on tokenized measurement data. A trained MSO model identifies measurement signal objects most highly correlated to parameters of interest.

### CROSS REFERENCE TO RELATED APPLICATION

The present application for patent claims priority under 35 U.S.C. § 119 from U.S. provisional patent application Ser. No. 63/711,717, filed Oct. 25, 2024, entitled, “Feature Transformer Architecture for Optical and X-ray Metrology of Semiconductor Process Control,” the subject matter of which is incorporated herein by reference in its entirety.

### TECHNICAL FIELD

The described embodiments relate to semiconductor metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. A number of x-ray and optical metrology based techniques including scatterometry, ellipsometry, and reflectometry implementations and associated analysis algorithms are commonly used to characterize critical dimensions, film thicknesses, composition and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. For example, modern memory structures are often high-aspect ratio, three-dimensional structures fabricated from opaque materials that make it difficult for optical radiation to penetrate to the bottom layers.

To overcome penetration depth issues, traditional imaging techniques such as TEM, SEM etc., are employed with destructive sample preparation techniques such as focused ion beam (FIB) machining, ion milling, blanket or selective etching, etc. For example, transmission electron microscopes (TEM) achieve high resolution levels and are able to probe arbitrary depths, but TEM requires destructive sectioning of the specimen. Several iterations of material removal and measurement generally provide the information required to measure the critical metrology parameters throughout a three dimensional structure. But, these techniques require sample destruction and lengthy process times. The complexity and time to complete these types of measurements introduces large inaccuracies due to drift of etching and metrology steps. In addition, these techniques require numerous iterations which introduce registration errors.

Optical based metrology systems and transmission based X-ray scatterometry systems offer the potential for high-throughput, non-destructive measurement of many advanced targets (e.g., complex 3D structures, structures smaller than 10 nm, structures employing opaque materials) and measurement applications (e.g., line edge roughness and line width roughness measurements). In some examples, Spectroscopic Ellipsometry (SE) and Spectroscopic Reflectometry (SR) are employed as in-line monitoring and control metrologies for Critical Dimensions (CD) and film characterization in FinFET and Gate-All-Around (GAA) logic and DRAM development and production.

Measurement recipe development is a critical step to realizing a successful model based measurement of a semiconductor structure. The measurement recipe specifies the set of measurement signals to be collected, any mathematical pre-processing of the collected signals, and the measurement model that operates on the measurement signals to arrive at estimated values of one or more parameters of interest characterizing a semiconductor structure under measurement.

In some examples, optical and x-ray based metrology systems employ indirect methods of measuring physical properties of a specimen under measurement. In some examples, a physics-based measurement model is created that attempts to predict raw measurement signals based on assumed values of one or more model parameters. In some examples, the raw measurement signals are Mueller Matrix signals as a function of illumination wavelength, harmonic signals as a function of wavelength, image pixel intensity as a function of image location, etc., collected at one or more angles of incidence and azimuth angles. The measurement model includes parameters associated with the metrology tool itself, e.g., system parameters and parameters associated with the specimen under measurement. When solving for parameters of interest, some specimen parameters are treated as fixed valued and other specimen parameters of interest are floated, i.e., resolved based on the raw measurement signals.

System parameters are parameters used to characterize the metrology tool. Exemplary system parameters include angle of incidence (AOI), azimuth angle, beam divergence, etc. Specimen parameters are parameters used to characterize the specimen (e.g., material and geometric parameters characterizing the structure(s) under measurement). For a thin film specimen, exemplary specimen parameters include refractive index, dielectric function tensor, nominal layer thickness of all layers, layer sequence, etc. For a CD specimen, exemplary specimen parameters include geometric parameter values associated with different layers, refractive indices associated with different layers, etc. For measurement purposes, the system parameters and many of the specimen parameters are treated as known, fixed valued parameters. However, the values of one or more of the specimen parameters are treated as unknown, floating parameters of interest.

In some examples, the values of the floating parameters of interest are resolved by an iterative process (e.g., regression) that produces the best fit between theoretical predictions and experimental data. The values of the unknown, floating parameters of interest are varied and the model output values are calculated and compared to the raw measurement data in an iterative manner until a set of specimen parameter values are determined that results in a sufficiently close match between the model output values and the experimentally measured values. In general, matching is achieved on a wavelength level for spectroscopic based measurements and a pixel level for image based measurements for all measurement channels, e.g., each measured AOI, each measured Azimuth angles, each measured Mueller Matrix element, etc.

In some other examples, the floating parameters are resolved by a search through a library of pre-computed solutions to find the closest match. The library is generated apriori based on the regression model to reduce run-time computational effort.

In some other examples, a Machine-Learning (ML) based measurement model is trained to estimate values of one or more parameters of interest based on the collected measurement signals. Training data includes real measurement signals and corresponding known values of the parameters of interest, synthetically generated measurement signals and corresponding known values of the parameters of interest, or both. Often, the synthetic measurement signals are generated using a physics-based measurement model.

The indirect approach to estimating values of parameters of interest is challenging to implement due to the complexity of the measurement model required to adequately represent light scattered from a complex semiconductor structure. The measurement model must properly model both the device under measurement and the measurement system to adequately model the physical interaction between the two, i.e., the light scattered from the device under measurement. Lack of measurement sensitivity and parameter correlation limit measurement performance. ML based measurement modeling suffers from a lack of robustness to process variation and extremely long measurement model development time. Furthermore, traditional machine learning based measurement models rely on accurate physical measurement models to generate sufficiently accurate training data. Thus, a lack of sufficiently accurate physical measurement models adversely limits machine learning based measurement models.

In general, measurement recipe development for model based measurements is limited by a lack of measurement signal sensitivity to structural parameters characterizing the features to be measured and challenges associated with selecting combinations of different measurement signals that provide measurement signal sensitivity to the structural parameters of interest.

For example, optical metrology tools utilizing infrared to visible light can penetrate many layers of translucent materials. Longer wavelengths penetrate deeply into high aspect ratio structures, but measurement sensitivity to small anomalies is limited. In addition, the increasing number of parameters required to characterize complex structures, leads to increasing parameter correlation. As a result, the parameters characterizing the target often cannot be reliably decoupled with available measurement models.

To overcome these challenges, optical and x-ray based metrology tools are configured to collect data over increasingly larger ranges of system parameters, e.g., larger wavelength ranges, larger ranges of azimuth angles and angles of incidence, full Mueller Matrix data collection, etc. The increased amount of available data increases the likelihood that a successful measurement recipe can be generated, but it also dramatically increases the time and computational effort associated with the development process. In many measurement applications, existing techniques are unable to select combinations of different measurement signals that provide sufficient measurement signal sensitivity to the structural parameters of interest.

For example, it is becoming challenging to generate successful recipes associated with many CD and film measurement applications associated with the latest device structures, including GAA, CFET, logic devices, and DRAM, manufactured at current and upcoming production nodes. Challenges include excessive development times, lack of robustness to process variations, and insufficient measurement accuracy.

To further improve device performance, the semiconductor industry continues to focus on vertical integration. Thus, accurate measurement of complex, fully three dimensional structures is crucial to ensure viability and continued scaling improvements. Future metrology applications present challenges for metrology due to increasingly small resolution requirements, multi-parameter correlation, increasingly complex geometric structures including high aspect ratio structures, and increasing use of opaque materials. Furthermore, the computational burden and development time required to generate an accurate measurement model for optical and x-ray based measurements of complex semiconductor structures is a significant barrier to high throughput metrology of modern semiconductor devices. Thus, methods and systems for improved optical and x-ray based measurements are desired.

### SUMMARY

Methods and systems for measurements of complex semiconductor structures employing measurement signal combinations derived from optical, x-ray, or electron based measurements of the structure of interest are described herein. The derived measurement signal combinations highlight signal features that exhibit enhanced sensitivity to one or more parameters of interest characterizing the semiconductor structure under measurement.

In one aspect, one or more measurement signal combinations are analytically derived by operation of a mathematical function or combination of multiple mathematical functions on measurement signals associated with measurements of the structure of interest. By way of non-limiting example, the one or more mathematical functions include addition, subtraction, multiplication, etc.

In general, analytically derived measurement signal combinations offer the potential to improve signal sensitivity in both forward and inverse recipe training by adding additional analytic features with increased complexity and nonlinearity across measurement signals. Measurement signal combinations potentially eliminate the need for exhaustive manual measurement signal selection or filtering to isolate signals with strong correlation to parameters of interest.

In another aspect, one or more measurement signal combinations are derived by operation of a Measurement Signal Object (MSO) model on measurement signals associated with measurements of the structure of interest. An MSO model is determined using a transformer architecture employing an attention mechanism operating on tokenized measurement data. The tokenized measurement data is associated with a set of measurements at different values of one or more independent measurement system parameters and corresponding values of one or more parameters of interest. A trained MSO model identifies data features, including independent system parameter values, most highly correlated to the parameters of interest. In this manner, a trained MSO model facilitates measurement recipe development by eliminating sets of system parameter values that are not strongly correlated to the parameters of interest, and thus, are not acquired during production operation.

Furthermore, a trained MSO model identifies data features, i.e., measurement signal objects, most highly correlated to the parameters of interest. This enhances data features corresponding to parameters of interest, reduces correlation among parameters of interest, and reduces the dimension of the measurement data required to estimate values of the parameters of interest. A trained MSO model operates on tokenized measurement data sets. The attention mechanism enables improved regression performance and machine learning based model training in lower dimension spaces, which, in turn reduces computational effort significantly, e.g., 3 orders of magnitude, or more in some examples.

In a further aspect, a MSO Principal Component (PC) transform model is trained based on measurement data associated with a set of measurements at different values of one or more independent measurement system parameters and corresponding values of one or more parameters of interest.

In another aspect, a trained Measurement Signal Combination-Machine Learning (MSC-ML) based measurement model is employed to estimate values of parameters of interest characterizing a structure under measurement from a set of measurement signals. The estimation of the values of the parameters of interest is based at least in part on measurement signal combinations derived from the measurement signals.

The use of different types of measurement signal combinations enables the extraction of more detailed measurement signal information associated with the structural parameters of interest. The different parameters of interest are represented in different data spaces, i.e., MSOs, principle components, pixel or wavelength intensities, compared to earlier methods relying on pixel or wavelength intensities only.

In a further aspect, a MSC-ML based measurement model is trained based on measurement data associated with a set of measurements at different values of one or more independent measurement system parameters and corresponding values of one or more parameters of interest.

In another aspect, measurement signal combinations are employed in the context of a model based regression analysis to estimate values of one or more parameters of interest characterizing a structure under measurement. In some examples, measurement signal combinations enable improved robustness of regression based measurement solutions.

In one further aspect, model fitting to measurement signal combinations reduces computational effort to arrive at a solution and improves measurement robustness.

In another further aspect, estimated values of parameters of interest generated by a trained MSC-ML based measurement model are employed to seed a model based regression analysis of measurement signals.

In another further aspect, estimated values of parameters of interest generated by a trained MSC-ML based measurement model are employed to regularize a model based regression analysis of measurement signals.

In another aspect, measurement signal combinations are employed as conditional input to train machine learning based or library based measurement models. In some examples, the resulting measurement models reduce computational effort, increase measurement accuracy, and increased model stability.

Providing measurement signal combinations as conditional input to a machine learning based measurement model enables the model to utilize additional feature information that may not be captured in synthetically generated DOE training data.

In another aspect, a MSC-ML based measurement model is trained with estimated values of parameters of interest derived from a Rigorous Coupled Wave Analysis (RCWA) engine provided as conditional input to the MSC-ML based measurement model.

In another aspect, a trained RCWA conditioned ML based measurement model is employed to estimate values of parameters of interest characterizing a structure under measurement from a set of measurement signals. The estimation of the values of the parameters of interest is based at least in part on measurement signal combinations derived from the measurement signals and values of the one or more parameters of interest estimated by a RCWA solver employed as conditional input to the trained RCWA conditioned ML based measurement model.

In a further aspect, DOE sets of measurement signals are synthetically generated based on multiple values of one or more material parameters characterizing the material characteristics of a structure under measurement. In one example, DOE sets of measurement signals are generated for a nominal value of one or more material parameters and for different, perturbed values of the one or more material parameters. The perturbed values of the one or more material parameters strongly modulates the measurement signals, e.g., Mueller Matrix intensity values, spectral intensity values, etc., while preserving the DOE values of structural parameters of interest, e.g., CD, thickness, etc. This reduces correlation among measurement signals, enhances measurement signal sensitivity, and improves measurement model robustness.

In some examples, a training set of measurement signals includes measurement signals generated by a measurement of a semiconductor structure at a prior process state.

In general, measurement functionality based on measurement signal combinations as described herein may be implemented on any number of different metrology systems, including, but not limited to, various X-ray based measurement modalities, such as X-ray scatterometry, X-ray reflectometry, X-ray diffraction, X-ray fluorescence, etc., various optically based measurement modalities, such as spectroscopic reflectometry, scatterometry, and ellipsometry, image based reflectometry, etc., and various electron beam based measurement modalities, such as model based electron beam metrology.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a Measurement Signal Object (MSO) transform training engine in one embodiment.

FIG. 2 is a diagram illustrative of a Measurement Signal Object - Principal Component (MSO-PC) transform training engine in one embodiment.

FIG. 3 is a diagram illustrative of a Measurement Signal Object - Machine Learning (MSC-ML) based measurement engine in one embodiment.

FIG. 4 is a diagram illustrative of a Measurement Signal Combination - Machine Learning (MSC-ML) based measurement model training engine 190 in one embodiment.

FIG. 5 is a diagram illustrative of a Measurement Signal Combination (MSC) enhanced regression based measurement engine in one embodiment.

FIG. 6 is a diagram illustrative of a Measurement Signal Combination (MSC) conditioned measurement model training engine in one embodiment.

FIG. 7 is a diagram illustrative of a Measurement Signal Combination (MSC) conditioned measurement engine in one embodiment.

FIG. 8 is a diagram illustrative of a Rigorous Coupled Wave Analysis (RCWA) conditioned measurement model training engine in one embodiment.

FIG. 9 is a diagram illustrative of a Rigorous Coupled Wave Analysis (RCWA) conditioned measurement engine in one embodiment.

FIG. 10 illustrates an embodiment of a Transmission, Small-Angle X-Ray Scatterometry (T-SAXS) metrology tool for measuring characteristics of a specimen based on measurement signal combinations in accordance with the exemplary methods presented herein.

FIG. 11 illustrates an embodiment of a spectroscopic ellipsometry based measurement system for measuring characteristics of a specimen based on measurement signal combinations in accordance with the exemplary methods presented herein.

FIG. 12 illustrates a flowchart illustrative of a method for measuring characteristics of a specimen based on measurement signal combinations in one example.

### DETAILED DESCRIPTION

Reference will now be made in detail to background examples and some embodiments of the invention, examples of which are illustrated in the accompanying drawings.

Methods and systems for measurements of complex semiconductor structures employing measurement signal combinations derived from optical, x-ray, or electron based measurements of the structure of interest are described herein. The derived measurement signal combinations highlight signal features that exhibit enhanced sensitivity to one or more parameters of interest characterizing the semiconductor structure under measurement.

The methods and systems described herein are particularly applicable to measurements of semiconductor structures having low measurement signal sensitivity, high parameter correlation, or both. Furthermore, the semiconductor structures are typically characterized by a relatively large number of parameters of interest. Data sets derived from measurement signal combinations enable reduced measurement recipe development time, a.k.a., time to solution (TTS), increased measurement accuracy, increased measurement robustness to process variations, reduced measurement run time, and reduced signal acquisition time for optical CD and film measurements, x-ray scatterometry based measurements, etc.

Data sets based on measurement signal combinations reduce runtime compared to traditional measurement models. This enables significantly reduced Move-Acquire-Move (MAM) times. In some examples, measurement signal combinations enable measurement recipes requiring fewer different measurements. Typically, measurement signals are collected at a number of different values of one or more measurement system parameters, e.g., angles of incidence, azimuth angle, illumination wavelength, polarization state, etc., in accordance with a measurement recipe. Values of one or more parameters of interest are determined based on the collected measurement signals. It follows that measurement time decreases as the number of measurements required by a specific measurement recipe decreases.

The methods and systems described herein enable non-destructive metrology and process monitoring and control of the semiconductor fabrication process for complex devices, including, but not limited to, 3D NAND, conventional DRAM, 3D DRAM, 3D FLASH, and future devices with complex patterning and deep structure etch. Moreover, the methods and systems described herein enable effective measurements of more process steps during measurement recipe development and production.

More specifically, the methods and systems described herein benefit measurement applications including, but not limited to, CD and film metrology of Logic FinFET devices, GAA lithography and Etch patterning processes, GAA SiGe/Si superlattice structures, High-K metal gate structures employed to tune threshold voltage, DRAM etch, capacitance measurements, and High-K metal gate structures in peripheral circuits.

In some embodiments, measurement signal combinations are employed in the context of a model based regression analysis to estimate values of one or more parameters of interest characterizing a structure under measurement. In some examples, model fitting to measurement signal combinations reduces computational effort to arrive at a solution and improves measurement robustness.

In some embodiments, data sets derived from measurement signal combinations are employed to train machine learning based or library based measurement models. In some examples, the resulting measurement models reduce computational effort, increase measurement accuracy, and increase model stability.

In one aspect, one or more measurement signal combinations are analytically derived by operation of a mathematical function or combination of multiple mathematical functions on measurement signals associated with measurements of the structure of interest. By way of non-limiting example, the one or more mathematical functions include addition, subtraction, multiplication, etc.

In one example, a spectroscopic ellipsometry system captures Mueller Matrix measurement signals expressed in the form of a Mueller Matrix. Traditionally, model based regression or ML based measurements are performed based on the Mueller Matrix signals directly. However, in this example, one or more measurement signal combinations are determined from a mathematical function or combination of multiple mathematical functions operating on the Mueller Matrix measurement signals, and model based regression or ML based measurements are performed based on the derived measurement signal combinations. Mathematical operations employed to derive the measurement signal combinations includes, but are not limited to, addition, subtraction, multiplication, transpose, inverse, and trace of the Mueller Matrix, M. In one example, measurement signal combinations are derived from the mathematical operation, (M+M′), wherein M′ denotes the transpose of the Mueller matrix. Other exemplary mathematical operations employed to derive measurement signal combinations include, but are not limited to, (M+M′), (M−M′) and their respective second order functions, Trace (M*M′), Trace (M+M′), etc.

In general, analytically derived measurement signal combinations offer the potential to improve signal sensitivity in both forward and inverse recipe training by adding additional analytic features with increased complexity and nonlinearity across measurement signals. Measurement signal combinations potentially eliminate the need for exhaustive manual measurement signal selection or filtering to isolate signals with strong correlation to parameters of interest. In some examples, spectra toggling or signal outliers are more readily identified and removed or their impact reduced significantly by employing measurement signal combinations. In addition, measurement signal combinations potentially reduce the computational effort associated with performing measurements by employing specific measurement signal combinations, rather than the full set of Mueller Matrix measurement signals.

In another aspect, one or more measurement signal combinations are derived by operation of a Measurement Signal Object (MSO) model on measurement signals associated with measurements of the structure of interest. An MSO model is determined using a transformer architecture employing an attention mechanism operating on tokenized measurement data associated with a set of measurements at different values of one or more independent measurement system parameters and corresponding values of one or more parameters of interest. A trained MSO model identifies data features, including independent system parameter values, most highly correlated to the parameters of interest. In this manner, a trained MSO model facilitates measurement recipe development by eliminating sets of system parameter values that are not strongly correlated to the parameters of interest, and thus, are not acquired during production operation.

Furthermore, a trained MSO model identifies data features, i.e., measurement signal objects, most highly correlated to the parameters of interest. This enhances data features corresponding to parameters of interest, reduces correlation among parameters of interest, and reduces the dimension of the measurement data required to estimate values of the parameters of interest. A trained MSO model operates on tokenized measurement data sets. The attention mechanism enables improved regression performance and machine learning based model training in lower dimension spaces, which, in turn reduces computational effort significantly, e.g., 3 orders of magnitude, or more in some examples.

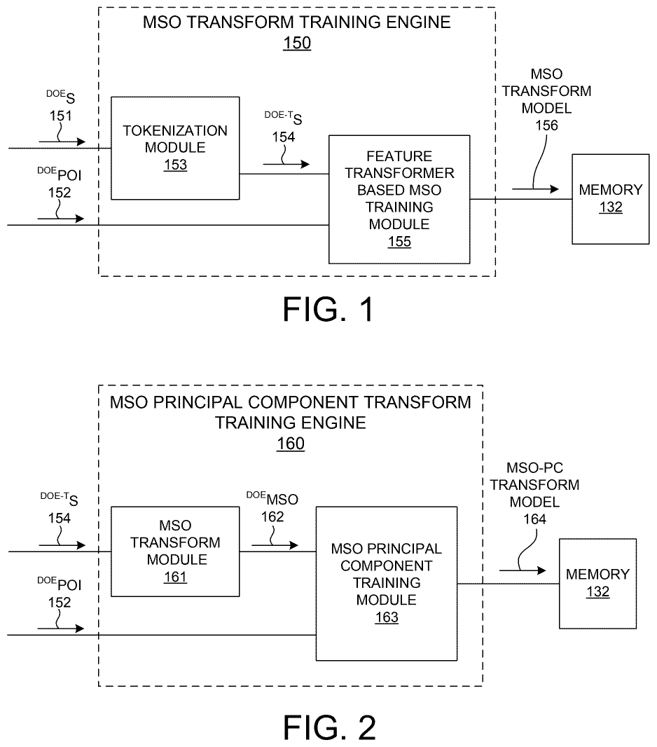

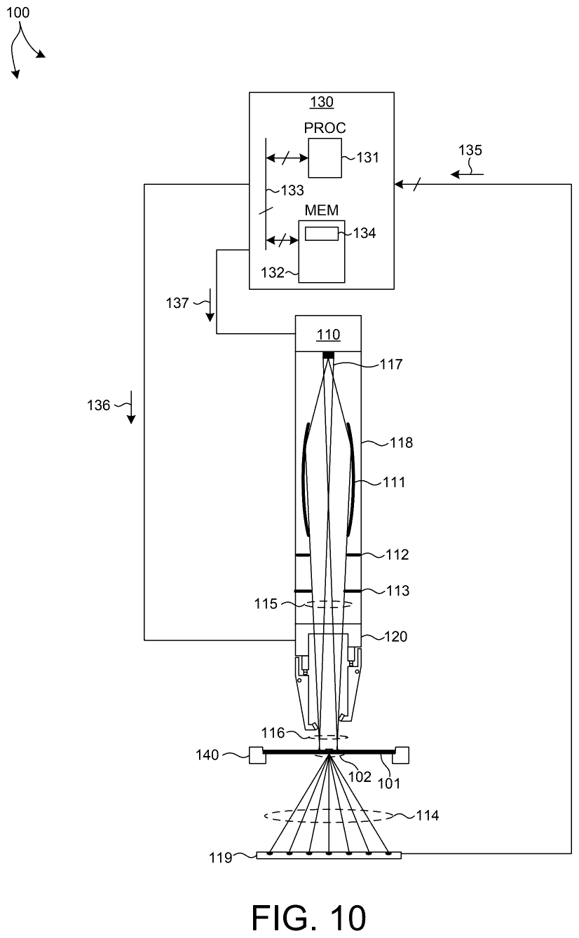

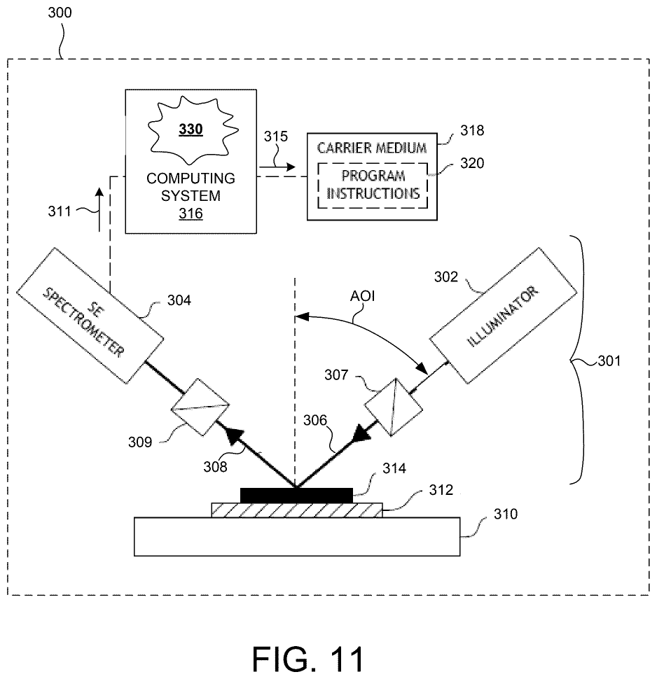

FIG. 1 is a diagram illustrative of a MSO transform training engine 150 implemented by a computing system associated with one or more metrology systems, such as computing system 130 depicted in FIG. 10 and computing system 330 depicted in FIG. 11. As depicted in FIG. 1, MSO transform training engine 150 includes tokenization module 153 and feature transform based MSO training module 155.

As depicted in FIG. 1, MSO transform training engine 150 receives Design Of Experiments (DOE) sets of measurement signals, ^{DOE}S 151, and values of one or more parameters of interest, ^{DOE}POI 152, corresponding to each set of DOE measurement signals. In some examples, the DOE sets of measurement signals are actual measurement signals performed by a metrology system associated with a measurement recipe under consideration and corresponding values of parameters of interest determined from a trusted reference measurement system. In some other examples, the DOE sets of measurement signals and corresponding values of parameters of interest are simulated. In practice, it is often the case that the DOE sets of measurement signals and corresponding values of parameters of interest include a combination of simulated and actual measurement results.

Tokenization module 153 tokenizes the DOE sets of measurement signals, ^{DOE}S 151, to generate a tokenized, DOE vector of measurement signals, ^{DOE-T}S 154. In one example, DOE sets of measurement signals, ^{DOE}S 151, includes DOE sets of Mueller Matrix intensities associated with different Azimuth angles, different angles of incidence, and different illumination wavelengths. In this example, tokenization module 153 generates a tokenized vector of intensity associated with each Mueller Matrix element (M), azimuth angle (Az), angle of incidence (AOI), and illumination wavelength (λ). The tokenized vector defines a [Az, AOI, M, λ] measurement signal space that enables independent mathematical operation across Az, AOI, M, and λ, independently, or in any combination. The tokenized structure better captures the features in the data and relations to the pattern structure dimensions, e.g., parameters of interest such as CD, overlay, film thickness, material composition, etc.

The tokenized, DOE vector of measurement signals, ^{DOE-T}S 154, and associated values of the parameters of interest, ^{DOE}POI 152, are communicated to feature transformer based Measurement Signal Object (MSO) training module 155. Feature transformer based MSO training module 155 generates a MSO transform model 156 that defines a set of measurement signal objects (MSOs) from the tokenized, DOE vector of measurement signals, ^{DOE-T}S 154, that strongly correlates with the values of the parameters of interest, ^{DOE}POI 152. The MSO transform model 156 is derived using a feature based transformer with an attention mechanism to identify portions of the tokenized data set that are strongly correlated with the parameters of interest. The resulting MSO transform model 156 is stored in memory, e.g., memory 132. In some examples, MSO transform model 156 is a selection matrix, w, that operates on measurement data in the [Az, AOI, M, λ] measurement signal space, e.g., w[Az, AOI, M, λ]. In this example, the MSO transform model 156 transforms the measurement signal space into a set of MSOs that depends on a single or a subset of Az, AOI, M, λ, or any combination thereof. During a measurement recipe generation phase, an MSO transform model 156 identifies a reduced set of measurements required to accurately measure one or more parameters of interest. Furthermore, in some examples, an MSO transform model 156 reduces the dimension of measurement data involved in a model based measurement of one or more parameters of interest. In one example, the dimension of measurement data is reduced from 200 to less than 20 independent variables. The tokenized data construction enables a transformer based computational architecture for all computation operations, which, in turn, is applied to supervised or unsupervised machine learning.

The measurement signal objects derived from the operation of a MSO transform model 156 on a set of measurement data can take many forms. In one example, a critical dimension object associated with CDSAXS measurements includes the intensity of pixels along a hexagon shape in image space and the intensity of pixels across the edges of the hexagon shape. In another example, a tilt object associated with CDSAXS measurements is a specific combination of Mueller Matrix elements. In another example, a locality object associated with CDSAXS measurements is the dark spaces between diffraction order peaks. Other measurement signal objects include depth objects, overlay objects, etc.

A MSO transform model 156 extracts measurement signal features that are representative of the parameter of interest characterizing a patterned structure, e.g., critical dimension, film thickness, in-die Overlay (IDO), etc. During the recipe development process, the derived measurement signal objects are employed to identify sub-spaces of the available measurement data set that are relevant to the measurement application. In this manner, a measurement recipe is developed that requires a reduced set of measurements to extract the patterning structure information in a faster, more accurate, manner. Consequently, measurement run-time and computational effort are reduced.

In a further aspect, a MSO Principal Component (PC) transform model is trained based on measurement data associated with a set of measurements at different values of one or more independent measurement system parameters and corresponding values of one or more parameters of interest.

FIG. 2 is a diagram illustrative of a MSO-PC transform training engine 160 implemented by a computing system associated with one or more metrology systems, such as computing system 130 depicted in FIG. 10 and computing system 330 depicted in FIG. 11. As depicted in FIG. 2, MSO-PC transform training engine 160 includes MSO transform module 161 and MSO-PC training module 163.

As depicted in FIG. 2, MSO-PC transform training engine 160 receives tokenized, DOE sets of measurement signals, ^{DOE-T}S 154, and values of one or more parameters of interest, ^{DOE}POI 152, corresponding to each set of DOE measurement signals. MSO transform module 161 includes MSO transform model 156, which operates on the tokenized, DOE sets of measurement signals, ^{DOE-T}S 154, to generate a set of DOE MSOs, ^{DOE}MSO 162, associated with the tokenized, DOE sets of measurement signals, ^{DOE-T}S 154. The set of DOE MSOs, ^{DOE}MSO 162, and the values of one or more parameters of interest, ^{DOE}POI 152, are communicated to MSO-PC training module 163. MSO-PC training module 163 generates a MSO-PC transform model 164 that defines a set of principal components from the set of DOE MSOs, ^{DOE}MSO 162, that strongly correlates with the values of the parameters of interest, ^{DOE}POI 152. The MSO-PC transform model 164 is derived using a principal component analysis to identify combinations of MSOs that are strongly correlated with the parameters of interest. The resulting MSO-PC transform model 164 is stored in memory, e.g., memory 132.

A MSO-PC transform model 164 extracts combinations of measurement signal objects that are most representative of the parameter of interest characterizing a patterned structure, e.g., critical dimension, film thickness, in-die Overlay (IDO), etc. In this manner, a MSO-PC transform model enables additional data reduction during both measurement recipe development and measurement run-time.

In another aspect, a trained Measurement Signal Combination-Machine Learning (MSC-ML) based measurement model is employed to estimate values of parameters of interest characterizing a structure under measurement from a set of measurement signals. The estimation of the values of the parameters of interest is based at least in part on measurement signal combinations derived from the measurement signals.

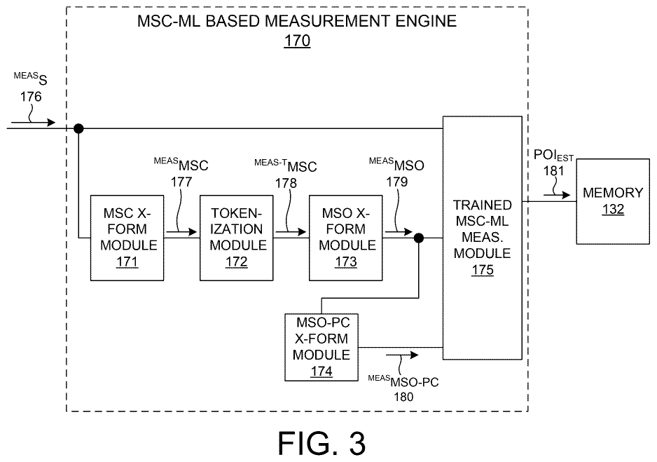

FIG. 3 is a diagram illustrative of a MSC-ML based measurement engine 170 implemented by a computing system associated with one or more metrology systems, such as computing system 130 depicted in FIG. 10 and computing system 330 depicted in FIG. 11. As depicted in FIG. 3, MSC-ML based measurement engine 170 includes Measurement Signal Combination (MSC) transform module 171, tokenization module 172, MSO transform module 173, MSO-PC transform module 174, and trained MSC-ML measurement module 175.

As depicted in FIG. 3, MSC-ML based measurement engine 170 receives measurement signals, ^{MEAS}S 176, collected by a metrology system, e.g., metrology systems 100 and 300 depicted in FIG. 10 and FIG. 11, respectively. In the embodiment depicted in FIG. 3, measurement signals, ^{MEAS}S 176, are communicated to Measurement Signal Combination (MSC) transform module 171 and trained MSC-ML measurement module 175.

MSC transform module 171 determines one or more measurement signal combinations from measurement signals, ^{MEAS}S 176, by operation of a mathematical function or combination of multiple mathematical functions. The resulting measurement signal combinations, ^{MEAS}MSC 177, are communicated to tokenization module 172. Tokenization module 172 tokenizes the measurement signal combinations, ^{MEAS}MSC 177, to generate a tokenized, vector of measurement signals, ^{MEAS-T}MSC 178, communicated to MSO transform module 173. MSO transform module 173 includes a MSO transform model, e.g., MSO transform model 156, which operates on the tokenized, measurement signal combinations, ^{MEAS-T}MSC 178, to generate a set of MSOs, ^{MEAS}MSO 179, communicated to trained MSC-ML measurement module 175 and MSO-PC transform module 174. The operation of the MSO transform model on the tokenized, vector of measurement signals, ^{MEAS-T}MSC 178, identifies portions of the tokenized data set that are strongly correlated with the parameters of interest by operation of the attention mechanism of the trained MSO transform model.

MSO-PC transform module 174 includes a MSO-PC transform model, e.g., MSO-PC transform model 164, that determines a set of principal components, ^{MEAS}MSO-PC 180, from the set of MSOs, ^{MEAS}MSO 179. The set of principal components of the measurement signal objects, ^{MEAS}MSO-PC 180, is also communicated to the trained MSC-ML measurement module 175.

In the embodiment depicted in FIG. 3, the trained MSC-ML measurement module 175 includes a trained MSC-ML measurement model that estimates values of one or more parameters of interest characterizing the structures under measurement based on the measurement signals, ^{MEAS}S 176, the derived MSOs, ^{MEAS}MSO 179, and the derived principal components of the MSOs, ^{MEAS}MSO-PC 180. The resulting estimated values of the parameters of interest are stored in memory, e.g., memory 132.

The embodiment depicted in FIG. 3 is provided by way of non-limiting example. In general, a trained MSC-ML measurement model is employed to estimate values of one or more parameters of interest characterizing the structures under measurement based on measurement signal combination signals, ^{MEAS}MSC 177, measurement signal objects, ^{MEAS}MSO 179, principal components of measurement signal objects, ^{MEAS}MSO-PC 180, individually or in any combination thereof. In some other examples, a trained MSC-ML measurement model is employed to estimate values of one or more parameters of interest characterizing the structures under measurement based on measurement signals, ^{MEAS}S 176, in combination with measurement signal combination signals, ^{MEAS}MSC 177, measurement signal objects, ^{MEAS}MSO 179, principal components of measurement signal objects, ^{MEAS}MSO-PC 180, individually or in any combination thereof.

The use of different types of measurement signal combinations enables the extraction of more detailed measurement signal information associated with the structural parameters of interest. The different parameters of interest are represented in different data spaces, i.e., MSOs, principle components, pixel or wavelength intensities, compared to earlier methods relying on pixel or wavelength intensities only. In some examples, DRAM IDOs, and DRAM and GAA Logic CD local variation (locality) are represented by measurement signal combinations derived from Mueller Matrix measurement signals. In some of these examples, determination of IDO and CD locality requires a small number of principal components of MSOs, e.g., less than 10, compared to 100 or more principal components of Mueller Matrix measurement signals in a typical Mueller Matrix measurement.

Although, the embodiment depicted in FIG. 3 illustrates measurement signal objects, ^{MEAS}MSO 179 determined from measurement signal combination signals, ^{MEAS}MSC 177, in general, in some other examples, measurement signal objects, ^{MEAS}MSO 179 are determined from measurement signals, ^{MEAS}S 176, directly.

In a further aspect, a MSC-ML based measurement model is trained based on measurement data associated with a set of measurements at different values of one or more independent measurement system parameters and corresponding values of one or more parameters of interest.

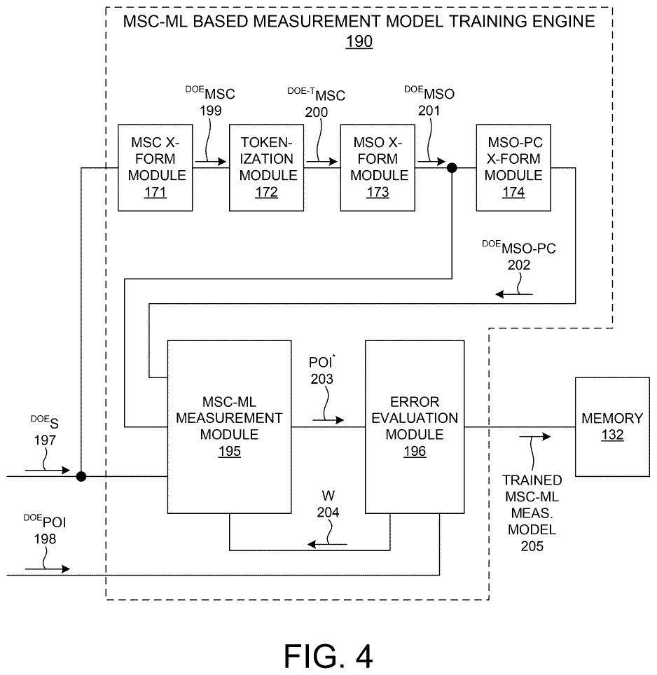

FIG. 4 is a diagram illustrative of a MSC-ML based measurement model training engine 190 implemented by a computing system associated with one or more metrology systems, such as computing system 130 depicted in FIG. 10 and computing system 330 depicted in FIG. 11. As depicted in FIG. 4, MSC-ML based measurement model training engine 190 includes Measurement Signal Combination (MSC) transform module 171, tokenization module 172, MSO transform module 173, MSO-PC transform module 174, MSC-ML measurement module 195, and error evaluation module 196.

As depicted in FIG. 4, MSC-ML based measurement model training engine 190 receives DOE sets of measurement signals, ^{DOE}S 197, and values of one or more parameters of interest, ^{DOE}POI 198, corresponding to each set of DOE measurement signals.

MSC transform module 171 determines one or more measurement signal combinations from DOE measurement signals, ^{DOE}S 197, by operation of a mathematical function or combination of multiple mathematical functions. The resulting measurement signal combinations, ^{DOE}MSC 199, are communicated to tokenization module 172. Tokenization module 172 tokenizes the measurement signal combinations, ^{DOE}MSC 199, to generate a tokenized, vector of measurement signals, ^{DOE-T}MSC 200, communicated to MSO transform module 173. MSO transform module 173 includes a MSO transform model, e.g., MSO transform model 156, which operates on the tokenized, measurement signal combinations, ^{DOE-T}MSC 200, to generate a set of MSOs, ^{DOE}MSO 201, communicated to MSC-ML measurement module 195 and MSO-PC transform module 174. The operation of the MSO transform model on the tokenized, vector of measurement signals, ^{DOE-T}S 200, identifies portions of the tokenized data set that are strongly correlated with the parameters of interest by operation of the attention mechanism of the trained MSO transform model.

MSO-PC transform module 174 includes a MSO-PC transform model, e.g., MSO-PC transform model 164, that determines a set of principal components, ^{DOE}MSO-PC 202, from the set of MSOs, ^{DOE}MSO 201. The set of principal components of the measurement signal objects, ^{DOE}MSO-PC 202, are also communicated to the MSC-ML measurement module 195.

MSC-ML based measurement module 195 includes a MSC-ML based measurement model that generates estimated values of one or more parameters of interest, POI* 203, based on the DOE sets of measurement signals, ^{DOE}S 197, the set of MSOs, ^{DOE}MSO 201, and the set of principal components of the MSOs, ^{DOE}MSO-PC 202. Error evaluation module 196 generates updated values of model weighting parameters of the MSC-ML based measurement model based on the difference between the estimated values of the one or more parameters of interest, POI* 203, and the DOE values of the one or more parameters of interest, ^{DOE}POI 198. The updated model weighting values, W 204, are communicated to MSC-ML based measurement module 195. The updated MSC-ML based measurement model again generates estimated values of one or more parameters of interest, POI* 203, based on the DOE sets of measurement signals, ^{DOE}S 197, the set of MSOs, ^{DOE}MSO 201, and the set of principal components of the MSOs, ^{DOE}MSO-PC 202 using the updated model weighting values. MSC-ML based measurement model training engine 190 iterates until an exit criteria is reached, e.g., the difference between the estimated values of the one or more parameters of interest, POI* 203, and the DOE values of the one or more parameters of interest, ^{DOE}POI 198, fall below predetermined threshold values, a maximum number of iterations in reached, etc. When the exit criteria are reached, the MSC-ML based measurement model training engine 190 communicates the trained MSC-ML based measurement model 205 to a memory, e.g., memory 132.

In the embodiment depicted in FIG. 4, the MSC-ML based measurement model training engine 190 is configured to train a MSC-ML measurement model that estimates values of one or more parameters of interest characterizing the structures under measurement based on the DOE measurement signals, ^{DOE}S 197, the derived MSOs, ^{DOE}MSO 201, and the derived principal components of the MSOs, ^{DOE}MSO-PC 202.

The embodiment depicted in FIG. 4 is provided by way of non-limiting example. In general, a MSC-ML based measurement model training engine can be configured to train a MSC-ML measurement model based on measurement signal combination signals, ^{DOE}MSC 199, measurement signal objects, ^{DOE}MSO 201, principal components of measurement signal objects, ^{DOE}MSO-PC 202, individually or in any combination thereof. In some other examples, a MSC-ML based measurement model training engine can be configured to train a MSC-ML measurement model based on measurement signals, ^{DOE}S 197, in combination with measurement signal combination signals, ^{DOE}MSC 199, measurement signal objects, ^{DOE}MSO 201, principal components of measurement signal objects, ^{DOE}MSO-PC 202, individually or in any combination thereof.

Although, the embodiment depicted in FIG. 4 illustrates measurement signal objects, ^{DOE}MSO 201 determined from measurement signal combination signals, ^{DOE}MSC 199, in general, in some other examples, measurement signal objects, ^{DOE}MSO 201 are determined from measurement signals, ^{DOE}S 197, directly.

In another aspect, measurement signal combinations are employed in the context of a model based regression analysis to estimate values of one or more parameters of interest characterizing a structure under measurement. In some examples, measurement signal combinations enable improved robustness of regression based measurement solutions.

In one further aspect, model fitting to measurement signal combinations reduces computational effort to arrive at a solution and improves measurement robustness.

In another further aspect, estimated values of parameters of interest generated by a trained MSC-ML based measurement model are employed to seed a model based regression analysis of measurement signals.

In another further aspect, estimated values of parameters of interest generated by a trained MSC-ML based measurement model are employed to regularize a model based regression analysis of measurement signals.

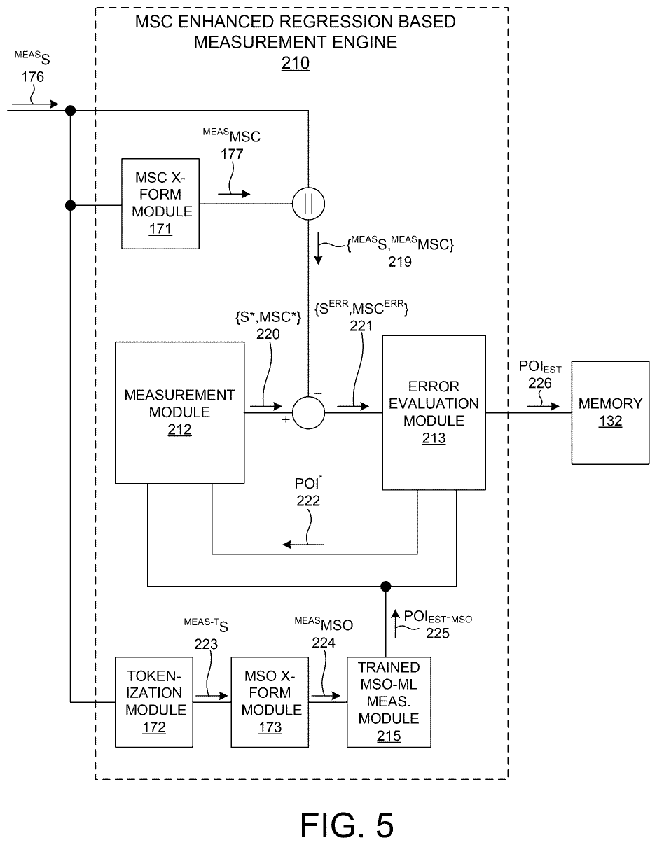

FIG. 5 is a diagram illustrative of a MSC enhanced regression based measurement engine 210 implemented by a computing system associated with one or more metrology systems, such as computing system 130 depicted in FIG. 10 and computing system 330 depicted in FIG. 11. As depicted in FIG. 5, MSC enhanced regression based measurement engine 210 includes Measurement Signal Combination (MSC) transform module 171, tokenization module 172, MSO transform module 173, trained MSO measurement module 215, measurement module 212, and error evaluation module 213.

As depicted in FIG. 5, MSC enhanced regression based measurement engine 210 receives sets of measurement signals, ^{MEAS}S 176, and estimates values of one or more parameters of interest, POI_{EST} 226, characterizing the structures under measurement based on the measurement signals.

MSC transform module 171 generates measurement signal combinations, ^{MEAS}MSC 177, from measurement signals, ^{MEAS}S 176, by operation of a mathematical function or combination of multiple mathematical functions. MSC enhanced regression based measurement engine 210 concatenates the measurement signal values, ^{MEAS}S, and the associated measurement signal combinations, ^{MEAS}MSC, into a vector {^{MEAS}S, ^{MEAS}MSC} 219.

As depicted in FIG. 5, measurement module 212 includes a measurement model, e.g., a physics based measurement model. The measurement model generates estimated measurement signal values, S*, based on the measurement model evaluated at the current values of the parameters of interest. Measurement module 212 also computes estimated measurement signal combinations, MSC*, associated with the estimated measurement signal values, S*, by operation of the mathematical function or combination of multiple mathematical functions embedded in MSC transform module 171. Measurement module 212 concatenates the measurement signal values, S*, and measurement signal combinations, MSC*, into a vector {S*, MSC*} 220.

MSC enhanced regression based measurement engine 210 computes the difference between the vector of measurement signal values and associated measurement signal combinations, {^{MEAS}S, ^{MEAS}MSC} 219, and the estimated vector of measurement signal values and associated measurement signal combinations, {S*, MSC*} 220 to generate an error vector of measurement signal values and associated measurement signal combinations, {S^{ERR}, MSC^{ERR}} 221.

Error evaluation module 213 generates updated values of the parameters of interest, POI* 222, based on the error vector 221. The updated values of the parameters of interest, POI* 222, are communicated to measurement module 212. The updated measurement model again generates estimated measurement signal values, S*, based on the measurement model evaluated at the current values of the parameters of interest, POI* 222. MSC enhanced regression based measurement engine 210 iterates until an exit criteria is reached, e.g., a measure of the magnitude of the error vector of measurement signal values and associated measurement signal combinations, {S^{ERR}, MSC^{ERR}} 221, falls below a predetermined threshold value, a maximum number of iterations in reached, changes in values of the parameters of interest fall below a predetermined threshold value, etc. When the exit criteria are reached, the MSC enhanced regression based measurement engine 210 communicates the estimated values of the parameters of interest, POI_{EST} 226, to a memory, e.g., memory 132.

As depicted in FIG. 5, tokenization module 172 tokenizes the measurement signals, ^{MEAS}S 176, to generate a tokenized vector of measurement signals, ^{MEAS-T}S 223, communicated to MSO transform module 173. MSO transform module 173 includes a MSO transform model, e.g., MSO transform model 156, which operates on the tokenized vector of measurement signals, ^{MEAS-T}S 223, to generate a set of MSOs, ^{MEAS}MSO 224, communicated to MSO-ML measurement module 215. The operation of the MSO transform model on the tokenized, vector of measurement signals, ^{MEAS-T}S 223, identifies portions of the tokenized data set that are strongly correlated with the parameters of interest by operation of the attention mechanism of the trained MSO transform model. Trained MSO-ML measurement module 215 includes a MSO-ML based measurement model that generates estimated values of one or more parameters of interest, POI_{EST-MSO} 225, based on the set of MSOs, ^{MEAS}MSO 224.

As depicted in FIG. 5, the values of one or more parameters of interest, POI_{EST-MSO} 225, estimated by the trained MSO-ML measurement module 215 are communicated to measurement module 212 and to error evaluation module 213. Measurement module 212 uses the estimated values of one or more parameters of interest, POI_{EST-MSO} 225, as seed values for the regression on the values of the parameters of interest. Error evaluation module 213 uses the estimated values of one or more parameters of interest, POI_{EST-MSO} 225, to regularize the optimization of the values of the parameters of interest at each iteration of the regression process.

In the embodiment depicted in FIG. 5, the MSC enhanced regression based measurement engine 210 is configured to enhance a regression based measurement by 1) performing model fitting to measurement signal combinations, in addition to measurement signals, 2) seeding the model based regression analysis of measurement signals using values of parameters of interest determined from measurement signal objects, and 3) regularizing a model based regression analysis of measurement signals using the values of parameters of interest determined from measurement signal objects.

The embodiment depicted in FIG. 5 is provided by way of non-limiting example. In general, a MSC enhanced regression based measurement engine can be configured to enhance a regression based measurement using any one of the improvements described hereinbefore, or any combination thereof.

In addition, in some other embodiments, the regression may be based on the measurement signal combination signals, ^{MEAS}MSC 177, measurement signal objects, ^{MEAS}MSO 224, principal components of measurement signal objects (not shown), individually or in any combination thereof. In some other examples, the regression may be based on measurement signals, ^{MEAS}S 176, in combination with the measurement signal combination signals, ^{MEAS}MSC 177, measurement signal objects, ^{MEAS}MSO 224, principal components of measurement signal objects (not shown), individually or in any combination thereof.

In another aspect, measurement signal combinations are employed as conditional input to train machine learning based or library based measurement models. In some examples, the resulting measurement models reduce computational effort, increase measurement accuracy, and increased model stability.

Providing measurement signal combinations as conditional input to a machine learning based measurement model enables the model to utilize additional feature information that may not be captured in synthetically generated DOE training data.

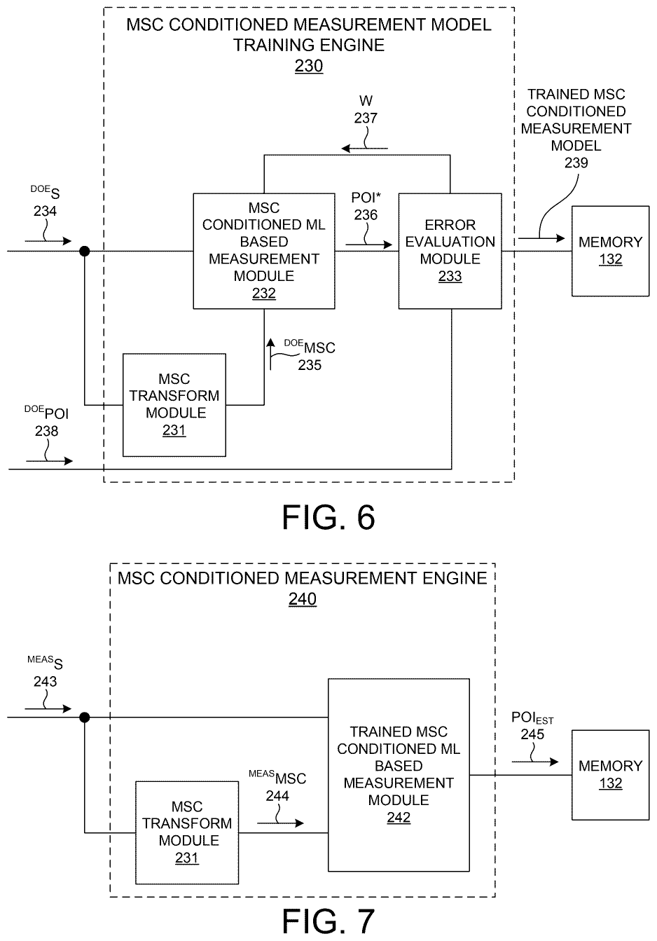

FIG. 6 is a diagram illustrative of a MSC conditioned measurement model training engine 230 implemented by a computing system associated with one or more metrology systems, such as computing system 130 depicted in FIG. 10 and computing system 330 depicted in FIG. 11. As depicted in FIG. 6, MSC conditioned measurement model training engine 230 includes Measurement Signal Combination (MSC) transform module 231, MSC conditioned machine-learning based measurement module 232, and error evaluation module 233.

As depicted in FIG. 6, MSC conditioned measurement model training engine 230 receives sets of DOE measurement signals, ^{DOE}S 234, and corresponding DOE values of one or more parameters of interest, ^{DOE}POI 238, characterizing the structures under measurement based on the measurement signals.

MSC transform module 231 generates DOE measurement signal combinations, ^{DOE}MSC 235, from DOE measurement signals, ^{DOE}S 234, by operation of a mathematical function or combination of multiple mathematical functions.

As depicted in FIG. 6, MSC conditioned machine-learning based measurement module 232 includes a MSC conditioned M-L based measurement model. The MSC conditioned M-L based measurement model generates estimated values of the parameters of interest, POI* 236, based on each set of DOE measurement signals, ^{DOE}S 234, provided as input, and the corresponding DOE measurement signal combinations, ^{DOE}MSC 235, provided to the model as conditional input.

Error evaluation module 233 generates updated values of weighting parameters of the MSC conditioned M-L based measurement model, W 237, based on the difference between the estimated values of the parameters of interest, POI* 236 and corresponding DOE values of one or more parameters of interest, ^{DOE}POI 238. The updated values of weighting parameters, W 237, are communicated to MSC conditioned machine-learning based measurement module 232. The MSC conditioned machine-learning based measurement model again generates estimated values of the parameters of interest, POI* 236, based on the updated weighting parameter values, W 237. MSC conditioned measurement model training engine 230 iterates until an exit criteria is reached, e.g., a measure of the magnitude of the difference between the estimated values of the parameters of interest, POI* 236 and corresponding DOE values of one or more parameters of interest, ^{DOE}POI 238, falls below a predetermined threshold value, a maximum number of iterations in reached, changes in estimated values of the parameters of interest fall below a predetermined threshold value, etc. When the exit criteria are reached, the MSC conditioned measurement model training engine 230 communicates the trained MSC conditioned measurement model 239, to a memory, e.g., memory 132.

FIG. 7 is a diagram illustrative of a MSC conditioned measurement engine 240 implemented by a computing system associated with one or more metrology systems, such as computing system 130 depicted in FIG. 10 and computing system 330 depicted in FIG. 11. As depicted in FIG. 7, MSC conditioned measurement engine 230 includes Measurement Signal Combination (MSC) transform module 231 and trained MSC conditioned machine-learning based measurement module 242.

As depicted in FIG. 7, MSC conditioned measurement engine 240 receives sets of measurement signals, ^{MEAS}S 243, associated with the measurement of a structure of interest. MSC transform module 231 generates measurement signal combinations, ^{MEAS}MSC 244, from measurement signals, ^{MEAS}S 243, by operation of a mathematical function or combination of multiple mathematical functions.

As depicted in FIG. 7, trained MSC conditioned machine-learning based measurement module 242 includes a trained MSC conditioned M-L based measurement model, e.g., model 239. The MSC conditioned M-L based measurement model generates estimated values of parameters of interest, POI_{EST} 245, based on measurement signals, ^{MEAS}S 243, provided as input, and corresponding measurement signal combinations, ^{MEAS}MSC 244, provided as conditional input. The MSC conditioned measurement engine 240 communicates estimated values of parameters of interest, POI_{EST} 245, to a memory, e.g., memory 132.

In another aspect, a MSC-ML based measurement model is trained with estimated values of parameters of interest derived from a Rigorous Coupled Wave Analysis (RCWA) engine provided as conditional input to the MSC-ML based measurement model.

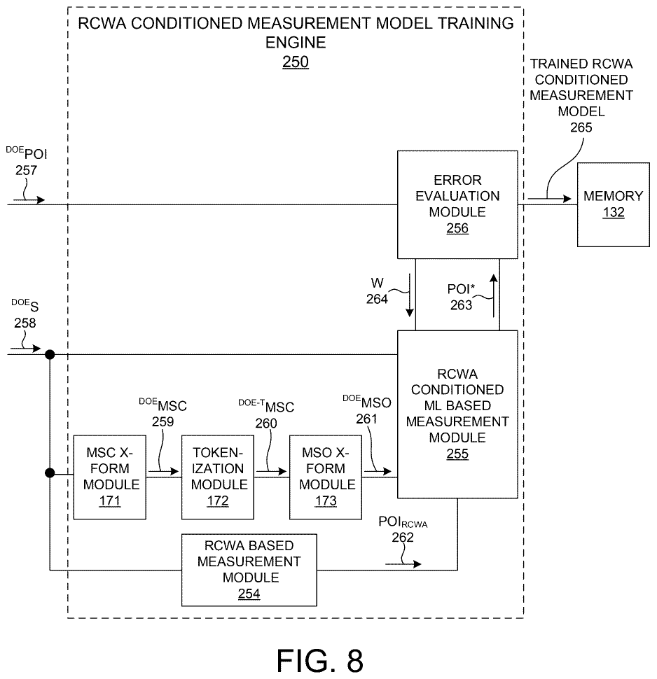

FIG. 8 is a diagram illustrative of a RCWA conditioned measurement model training engine 250 implemented by a computing system associated with one or more metrology systems, such as computing system 130 depicted in FIG. 10 and computing system 330 depicted in FIG. 11. As depicted in FIG. 8, RCWA conditioned measurement model training engine 250 includes Measurement Signal Combination (MSC) transform module 171, tokenization module 172, MSO transform module 173, RCWA based measurement module 254, RCWA conditioned ML based measurement module 255, and error evaluation module 256.

As depicted in FIG. 8, RCWA conditioned measurement model training engine 250 receives DOE sets of measurement signals, ^{DOE}S 258, and values of one or more parameters of interest, ^{DOE}POI 257, corresponding to each set of DOE measurement signals.

MSC transform module 171 determines one or more measurement signal combinations from DOE measurement signals, ^{DOE}S 258, by operation of a mathematical function or combination of multiple mathematical functions. The resulting measurement signal combinations, ^{DOE}MSC 259, are communicated to tokenization module 172. Tokenization module 172 tokenizes the measurement signal combinations, ^{DOE}MSC 259, to generate a tokenized, vector of measurement signal combinations, ^{DOE-T}MSC 260, communicated to MSO transform module 173. MSO transform module 173 includes a MSO transform model, e.g., MSO transform model 156, which operates on the tokenized, measurement signal combinations, ^{DOE-T}MSC 260, to generate a set of MSOs, ^{DOE}MSO 261, communicated to RCWA conditioned ML based measurement module 255. The operation of the MSO transform model on the tokenized, vector of measurement signal combinations, ^{DOE-T}MSC 260, identifies portions of the tokenized data set that are strongly correlated with the parameters of interest by operation of the attention mechanism of the trained MSO transform model.

RCWA based measurement module 254 includes a RCWA based solver employed to determine estimated values of one or more parameters of interest, POI_{RCWA} 262, corresponding to each set of DOE measurement signals, ^{DOE}S 258. The estimated values of the one or more parameters of interest, POI_{RCWA} 262, are communicated to RCWA conditioned ML based measurement module 255 as a conditional input to the RCWA conditioned ML based measurement model of RCWA conditioned ML based measurement module 255.

The RCWA conditioned ML based measurement model of RCWA conditioned ML based measurement module 255 generates estimated values of one or more parameters of interest, POI* 263, based on the DOE sets of measurement signals, ^{DOE}S 258 and the set of MSOs, ^{DOE}MSO 261, with the estimated values of the one or more parameters of interest, POI_{RCWA} 262, employed as conditional input. Error evaluation module 256 generates updated values of model weighting parameters, W 264, of the RCWA conditioned ML based measurement model based on the difference between the estimated values of the one or more parameters of interest, POI* 263, and the DOE values of the one or more parameters of interest, ^{DOE}POI 257. The updated model weighting values, W 264, are communicated to RCWA conditioned ML based measurement module 255. The updated RCWA conditioned ML based measurement model again generates estimated values of one or more parameters of interest, POI* 263, based on the DOE sets of measurement signals, ^{DOE}S 258 and the set of MSOs, ^{DOE}MSO 261, with the estimated values of the one or more parameters of interest, POI_{RCWA} 262, employed as conditional input, using the updated model weighting values. RCWA conditioned measurement model training engine 250 iterates until an exit criteria is reached, e.g., the difference between the estimated values of the one or more parameters of interest, POI* 263, and the DOE values of the one or more parameters of interest, ^{DOE}POI 257, fall below predetermined threshold values, a maximum number of iterations in reached, etc. When the exit criteria are reached, the RCWA conditioned ML based measurement model training engine 250 communicates the trained RCWA conditioned ML based measurement model 265 to a memory, e.g., memory 132.

In the embodiment depicted in FIG. 8, the RCWA conditioned measurement model training engine 250 is configured to train a RCWA conditioned ML based measurement model that estimates values of one or more parameters of interest characterizing the structures under measurement based on the DOE sets of measurement signals, ^{DOE}S 258 and the set of MSOs, ^{DOE}MSO 261, with the estimated values of the one or more parameters of interest, POI_{RCWA} 262, employed as conditional input.

The embodiment depicted in FIG. 8 is provided by way of non-limiting example. In general, a RCWA conditioned measurement model training engine can be configured to train a RCWA conditioned ML based measurement model based on measurement signal combination signals, ^{DOE}MSC 259, measurement signal objects, ^{DOE}MSO 261, principal components of measurement signal objects (not shown), individually or in any combination thereof. In some other examples, a RCWA conditioned measurement model training engine can be configured to train a RCWA conditioned ML based measurement model based on measurement signals, ^{DOE}S 258, with the estimated values of the one or more parameters of interest, POI_{RCWA} 262, employed as conditional input, in combination with measurement signal combination signals, ^{DOE}MSC 259, measurement signal objects, ^{DOE}MSO 261, principal components of measurement signal objects (not shown), individually or in any combination thereof.

Although, the embodiment depicted in FIG. 8 illustrates measurement signal objects, ^{DOE}MSO 261 determined from measurement signal combination signals, ^{DOE}MSC 259, in general, in some other examples, measurement signal objects, ^{DOE}MSO 261 are determined from measurement signals, ^{DOE}S 258, directly.

In another aspect, a trained RCWA conditioned ML based measurement model is employed to estimate values of parameters of interest characterizing a structure under measurement from a set of measurement signals. The estimation of the values of the parameters of interest is based at least in part on measurement signal combinations derived from the measurement signals and values of the one or more parameters of interest estimated by a RCWA solver employed as conditional input to the trained RCWA conditioned ML based measurement model.

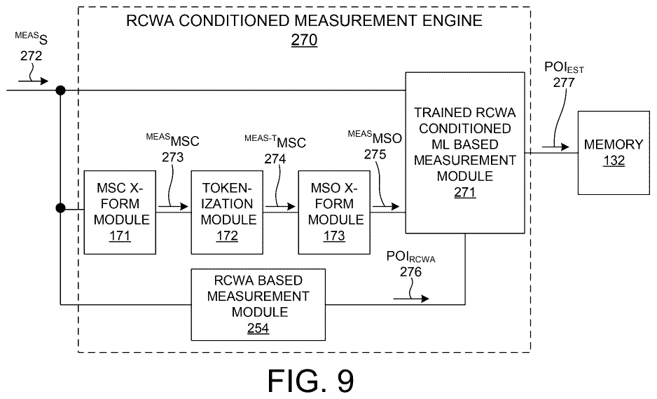

FIG. 9 is a diagram illustrative of a RCWA conditioned measurement engine 270 implemented by a computing system associated with one or more metrology systems, such as computing system 130 depicted in FIG. 10 and computing system 330 depicted in FIG. 11. As depicted in FIG. 9, RCWA conditioned measurement engine 270 includes Measurement Signal Combination (MSC) transform module 171, tokenization module 172, MSO transform module 173, RCWA based measurement module 254, and trained RCWA conditioned ML based measurement module 271.

As depicted in FIG. 9, a RCWA conditioned measurement engine 270 receives measurement signals, ^{MEAS}S 272, collected by a metrology system, e.g., metrology systems 100 and 300 depicted in FIG. 10 and FIG. 11, respectively. In the embodiment depicted in FIG. 9, measurement signals, ^{MEAS}S 272, are communicated to Measurement Signal Combination (MSC) transform module 171, RCWA based measurement module 254, and trained RCWA conditioned ML based measurement module 271.

MSC transform module 171 determines one or more measurement signal combinations from measurement signals, ^{MEAS}S 272, by operation of a mathematical function or combination of multiple mathematical functions. The resulting measurement signal combinations, ^{MEAS}MSC 273, are communicated to tokenization module 172. Tokenization module 172 tokenizes the measurement signal combinations, ^{MEAS}MSC 273, to generate a tokenized, vector of measurement signals, ^{MEAS-T}MSC 274, communicated to MSO transform module 173. MSO transform module 173 includes a MSO transform model, e.g., MSO transform model 156, which operates on the tokenized, measurement signal combinations, ^{MEAS-T}MSC 274, to generate a set of MSOs, ^{MEAS}MSO 275, communicated to trained RCWA conditioned ML based measurement module 271. The operation of the MSO transform model on the tokenized, vector of measurement signals, ^{MEAS-T}MSC 274, identifies portions of the tokenized data set that are strongly correlated with the parameters of interest by operation of the attention mechanism of the trained MSO transform model.

RCWA based measurement module 254 includes a RCWA based solver employed to determine estimated values of one or more parameters of interest, POI_{RCWA} 276, corresponding to each set of measurement signals, ^{MEAS}S 272. The estimated values of the one or more parameters of interest, POI_{RCWA} 276, are communicated to RCWA conditioned ML based measurement module 271 as a conditional input to the RCWA conditioned ML based measurement model of RCWA conditioned ML based measurement module 271.

In the embodiment depicted in FIG. 9, the trained RCWA conditioned ML based measurement module 271 includes a trained RCWA conditioned ML based measurement model that estimates values of one or more parameters of interest characterizing the structures under measurement based on the measurement signals, ^{MEAS}S 272, and the derived MSOs, ^{MEAS}MSO 275, with the estimated values of the one or more parameters of interest, POI_{RCWA} 276, provided as a conditional input to the RCWA conditioned ML based measurement model. The resulting estimated values of the parameters of interest, POI_{EST} 277, are stored in memory, e.g., memory 132.

The embodiment depicted in FIG. 9 is provided by way of non-limiting example. In general, a trained RCWA conditioned ML based measurement model is employed to estimate values of one or more parameters of interest characterizing the structures under measurement based on measurement signal combination signals, ^{MEAS}MSC 272, measurement signal objects, ^{MEAS}MSO 271, principal components of measurement signal objects (not shown), individually or in any combination thereof. In some other examples, a trained RCWA conditioned ML based measurement model is employed to estimate values of one or more parameters of interest characterizing the structures under measurement based on measurement signals, ^{MEAS}S 272, in combination with measurement signal combination signals, ^{MEAS}MSC 273, measurement signal objects, ^{MEAS}MSO 275, principal components of measurement signal objects (not shown), individually or in any combination thereof, with the estimated values of the one or more parameters of interest, POI_{RCWA} 276, provided as a conditional input to the RCWA conditioned ML based measurement model.

Although, the embodiment depicted in FIG. 9 illustrates measurement signal objects, ^{MEAS}MSO 275, determined from measurement signal combination signals, ^{MEAS}MSC 273, in general, in some other examples, measurement signal objects, ^{MEAS}MSO 275 are determined from measurement signals, ^{MEAS}S 272, directly.

FIG. 10 illustrates an embodiment of a Transmission, Small-Angle X-Ray Scatterometry (T-SAXS) metrology tool 100 for measuring characteristics of a specimen based on measurement signal combinations in accordance with the exemplary methods presented herein. As shown in FIG. 10, the system 100 may be used to perform T-SAXS measurements over an inspection area 102 of a specimen 101 illuminated by an illumination beam spot.

In the depicted embodiment, metrology tool 100 includes an x-ray illumination source 110 configured to generate x-ray radiation suitable for T-SAXS measurements. In some embodiments, the x-ray illumination source 110 is configured to generate wavelengths between 0.01 nanometers and 1 nanometer. In general, any suitable high-brightness x-ray illumination source capable of generating high brightness x-rays at flux levels sufficient to enable high-throughput, inline metrology may be contemplated to supply x-ray illumination for T-SAXS measurements. In some embodiments, an x-ray source includes a tunable monochromator that enables the x-ray source to deliver x-ray radiation at different, selectable wavelengths. As depicted in FIG. 10, computing system 130 is configured to control the x-ray illumination generated by x-ray illumination source 110 via control signals 137.

In some embodiments, one or more x-ray sources emitting radiation with photon energy greater than 15 keV are employed to ensure that the x-ray source supplies light at wavelengths that allow sufficient transmission through the entire device as well as the wafer substrate. By way of non-limiting example, any of a particle accelerator source, a liquid anode source, a rotating anode source, a stationary, solid anode source, a microfocus source, a microfocus rotating anode source, a plasma based source, and an inverse Compton source may be employed as x-ray illumination source 110. In one example, an inverse Compton source available from Lyncean Technologies, Inc., Palo Alto, California (USA) may be contemplated. Inverse Compton sources have an additional advantage of being able to produce x-rays over a range of photon energies, thereby enabling the x-ray source to deliver x-ray radiation at different, selectable wavelengths.

Exemplary x-ray sources include electron beam sources configured to bombard solid or liquid targets to stimulate x-ray radiation. Methods and systems for generating high brightness, liquid metal x-ray illumination are described in U.S. Pat. No. 7,929,667, issued on Apr. 19, 2011, to KLA-Tencor Corp., the entirety of which is incorporated herein by reference.

X-ray illumination source 110 produces x-ray emission over a source area having finite lateral dimensions (i.e., non-zero dimensions orthogonal to the beam axis. Focusing optics 111 focuses source radiation onto a metrology target located on specimen 101. The finite lateral source dimension results in finite spot size 102 on the target defined by the rays 117 coming from the edges of the source. In some embodiments, focusing optics 111 includes elliptically shaped focusing optical elements.

A beam divergence control slit 112 is located in the beam path between focusing optics 111 and beam shaping slit mechanism 120. Beam divergence control slit 112 limits the divergence of the illumination provided to the specimen under measurement. An additional intermediate slit 113 is located in the beam path between beam divergence control slit 112 and beam shaping slit mechanism 120. Intermediate slit 113 provides additional beam shaping. In general, however, intermediate slit 113 is optional.

Beam shaping slit mechanism 120 is located in the beam path immediately before specimen 101. In one aspect, the slits of beam shaping slit mechanism 120 are located in close proximity to specimen 101 to minimize the enlargement of the incident beam spot size due to beam divergence defined by finite source size. In one example, expansion of the beam spot size due to shadow created by finite source size is approximately one micrometer for a 10 micrometer x-ray source size and a distance of 25 millimeters between the beam shaping slits and specimen 101. As depicted in FIG. 10, computing system 130 is configured to control the size and shape of illumination beam 116 generated by beam shaping slit mechanism 120 via control signals 136.

In some embodiments, beam shaping slit mechanism 120 includes multiple, independently actuated beam shaping slits (i.e., blades). In one embodiment, beam shaping slit mechanism 120 includes four independently actuated beam shaping slits. These four beams shaping slits effectively block a portion of incoming beam 115 and generate an illumination beam 116 having a box shaped illumination cross-section.

In the embodiment depicted in FIG. 10, focusing optics 111, slits 112 and 113, and beam shaping slit mechanism 120 are maintained in a controlled environment (e.g., vacuum) within a flight tube 118.

In general, x-ray optics shape and direct x-ray radiation to specimen 101. In some examples, the x-ray optics include an x-ray monochromator to monochromatize the x-ray beam that is incident on the specimen 101. In some examples, the x-ray optics collimate or focus the x-ray beam onto measurement area 102 of specimen 101 to less than 1 milliradian divergence using multilayer x-ray optics. In these examples, the multilayer x-ray optics function as a beam monochromator, also. In some embodiments, the x-ray optics include one or more x-ray collimating mirrors, x-ray apertures, x-ray beam stops, refractive x-ray optics, diffractive optics such as zone plates, Montel optics, specular x-ray optics such as grazing incidence ellipsoidal mirrors, polycapillary optics such as hollow capillary x-ray waveguides, multilayer optics or systems, or any combination thereof. Further details are described in U.S. Patent Publication No. 2015/0110249, the content of which is incorporated herein by reference it its entirety.

X-ray detector 119 collects x-ray radiation 114 scattered from specimen 101 and generates an output signals 135 indicative of properties of specimen 101 that are sensitive to the incident x-ray radiation in accordance with a T-SAXS measurement modality. In some embodiments, scattered x-rays 114 are collected by x-ray detector 119 while specimen positioning system 140 locates and orients specimen 101 to produce angularly resolved scattered x-rays.

In some embodiments, a T-SAXS system includes one or more photon counting detectors with high dynamic range (e.g., greater than 10⁵). In some embodiments, a single photon counting detector detects the position and number of detected photons.

In some embodiments, the x-ray detector resolves one or more x-ray photon energies and produces signals for each x-ray energy component indicative of properties of the specimen. In some embodiments, the x-ray detector 119 includes any of a CCD array, a microchannel plate, a photodiode array, a microstrip proportional counter, a gas filled proportional counter, a scintillator, or a fluorescent material.

In this manner the X-ray photon interactions within the detector are discriminated by energy in addition to pixel location and number of counts. In some embodiments, the X-ray photon interactions are discriminated by comparing the energy of the X-ray photon interaction with a predetermined upper threshold value and a predetermined lower threshold value. In one embodiment, this information is communicated to computing system 130 via output signals 135 for further processing and storage.

In a further aspect, a transmission based, X-Ray scatterometry system, e.g., TSAXS measurement system 100, is employed to determine properties of a semiconductor structure (e.g., structural parameter values) based on one or more diffraction orders of scattered light. In the embodiment depicted in FIG. 10, computing system 130 is configured as a measurement engine configured to implement measurement signal combination based measurement functionality as described herein.

As depicted in FIG. 10, metrology tool 100 includes a computing system 130 employed to acquire signals 135 generated by detector 119 and determine properties of a semiconductor structure based at least in part on the acquired signals in accordance with measurement signal combination based measurement techniques described herein. In some embodiments, actual measurement signals and DOE measurement signal, as described herein with reference to FIGS. 1-9 are scattering response images generated by actual measurements performed by a transmission based X-Ray scatterometry system, such as T-SAXS metrology system 100 depicted in FIG. 10.

In some examples, a SAXS based measurement systems, such as T-SAXS metrology system 100, generates measurement signals to perform measurements of critical dimensions of complex memory structures in accordance with measurement signal combination based measurement techniques described herein. Critical Dimension, Small-Angle X-ray Scatterometery (CDSAXS) based measurements are critical to control yield of 3D NAND memory devices, DRAM memory devices, and emerging 3D DRAM devices. In these examples, the measurement signals include CDSAXS diffraction images collected at different angles of incidence, different azimuth angles, and different x-ray momentum resolution (Q). In particular, CDSAXS signals are known to include signal information corresponding to pattern structures under measurement, including CD profiles, tilt, and local CD variation. However, the raw data sets are extremely large, resulting in an excessive computational burden. Measurement signal combinations derived based on mathematical functions, the attention mechanism operating in a feature transformer architecture, or both, identify data features that correlate highly to parameters of interest, and reduce the dimension of the overall measurement data set required to estimate values of parameters of interest. This reduces time to solution, recipe development time, while improving solution robustness against process changes.

FIG. 11 illustrates an embodiment of a spectroscopic ellipsometry based measurement system 300 for measuring characteristics of a specimen based on measurement signal combinations in accordance with the exemplary methods presented herein. As shown in FIG. 11, system 300 may be used to perform spectroscopic ellipsometry measurements of one or more structures 314 of a semiconductor wafer 312 disposed on a wafer positioning system 310. In this aspect, the system 300 may include a spectroscopic ellipsometer equipped with an illuminator 302 and a spectrometer 304. The illuminator 302 of the system 300 is configured to generate and direct illumination of a selected wavelength range (e.g., 150-4500 nm) to the structure 314 disposed on the surface of the semiconductor wafer 312. In turn, the spectrometer 304 is configured to receive light from the surface of the semiconductor wafer 312. It is further noted that the light emerging from the illuminator 302 is polarized using a polarization state generator 307 to produce a polarized illumination beam 306. The radiation reflected by the structure 314 disposed on the wafer 312 is passed through a polarization state analyzer 309 and to the spectrometer 304. The radiation received by a detector of spectrometer 304 in the collection beam 308 is analyzed with regard to polarization state, allowing for spectral analysis of radiation passed by the analyzer. These spectra 311 are passed to the computing system 316 for analysis of the structure 314.

In a further embodiment, metrology system 300 includes one or more computing systems 316 employed to acquire signals 311 generated by a detector of spectrometer 304 and determine properties of a semiconductor structure based at least in part on the acquired signals in accordance with measurement signal combination based measurement techniques described herein. In some embodiments, computing system 316 includes one or more processors 330 configured to execute a measurement model training engine or measurement engine in accordance with the description provided herein. In the preferred embodiment, a measurement model training engine or measurement engine is a set of program instructions 320 stored on a carrier medium 318. The program instructions 320 stored on the carrier medium 318 are read and executed by one or more processors 330 of computing system 316 to realize measurement signal combination based model training or measurement functionality as described herein. The one or more computing systems 316 may be communicatively coupled to the spectrometer 304. In one aspect, the one or more computing systems 316 are configured to receive measurement signals 311 associated with a measurement (e.g., critical dimension, film thickness, composition, process, etc.) of the structure 314 of specimen 312. In one example, the measurement data 311 includes an indication of the measured spectral response (e.g., measured intensity as a function of wavelength) of the specimen by measurement system 300 based on the one or more sampling processes from the spectrometer 304. In some embodiments, the one or more computing systems 316 are further configured to determine values of one or more parameters of interest 315 characterizing the specimen under measurement from measurement data 311 in accordance with measurement signal combination based measurement techniques described herein.

In some embodiments, actual measurement signals and DOE measurement signal, as described herein with reference to FIGS. 1-9 are spectral signals generated by actual measurements performed by a spectroscopic measurement system, such as SE metrology system 300 depicted in FIG. 11.

In some other embodiments, actual measurement signals and DOE measurement signal, as described herein with reference to FIGS. 1-9 are contrast images generated by actual measurements performed by an electron based metrology system (not shown).

In general, measurements performed based on measurement signal combinations as described herein may be performed by many different semiconductor measurement systems, e.g., optical film metrology systems, optical critical dimension metrology systems, critical dimension small-angle x-ray scatterometry systems, electron based metrology systems, etc. Exemplary metrology systems configurable to generate measurement signals processed individually, or in combination, in accordance with the methods described herein, include, but are not limited to, spectroscopic ellisometry based metrology systems, spectroscopic reflectometry based metrology systems, Raman spectrometry based metrology systems, X-ray photoelectron spectroscopy based metrology systems, X-ray florescence based metrology systems, X-ray diffraction based metrology systems, etc.

As depicted hereinbefore, development of measurement models employing measurement signal combinations requires training on DOE measurement data sets. In some examples, the DOE sets of measurement signals and corresponding values of parameters of interest are simulated. Synthetically generated training data enables model training over a broader range of target geometries and measurement system settings without the need to generate additional real targets on the device to be measured. This saves computational effort and measurement time during measurement recipe development and results in measurement models with improved accuracy and robustness. In general, synthetically generated training data is simulated using measurement models corresponding to the same measurement tool and technologies employed in the actual measurement of semiconductor structures of interest in production, e.g., same measurement technology, same measurement system model, and same physical simulation models.

In a further aspect, DOE sets of measurement signals are synthetically generated based on multiple values of one or more material parameters characterizing the material characteristics of a structure under measurement. In one example, DOE sets of measurement signals are generated for a nominal value of one or more material parameters and for different, perturbed values of the one or more material parameters. The perturbed values are small excursions from the nominal value, e.g., less than 10% variation from the nominal value. The perturbed values of the one or more material parameters strongly modulates the measurement signals, e.g., Mueller Matrix intensity values, spectral intensity values, etc., while preserving the DOE values of structural parameters of interest, e.g., CD, thickness, etc. This reduces correlation among measurement signals, enhances measurement signal sensitivity, and improves measurement model robustness.

In some examples, a training set of measurement signals includes measurement signals generated by a measurement of a semiconductor structure at a prior process state. In some of these examples, a subset of the plurality of structural features of the semiconductor structure of interest are present at the prior process state. In this manner, the measurement signals are actual measurement signals, rather than synthetically generated measurement signals.

In some examples, prior state measurement data are employed to train a present state, measurement model. This approach takes advantage of the correlation between structural characteristics of measured samples fabricated before and after one or more intervening process steps. In these examples, a present state, measurement model is trained using training data associated with measurements of a plurality of instances of a current version of a semiconductor structure in a prior state of a semiconductor process flow.

A present state indicates the state of the semiconductor structure after the latest process step applied to the semiconductor structure, and before any subsequent process steps are applied to the semiconductor structure. A prior state indicates the state of the semiconductor structure before the latest process step was applied to the semiconductor structure. Prior state training data is derived from actual or simulated measurement of present or historical instances of the structure of interest fabricated on one or more production wafers in the i^{th} prior state, where i is any non-zero positive integer number bounded by the total number of prior process states before the present process state in the semiconductor fabrication process flow. In some examples, a significant amount of validated measurement data is collected from a semiconductor structure in a prior state. In some of these examples, accurate measurements of one or more parameters of interest in a prior state are relatively easy to obtain compared to a present state.

In some embodiments, a training data set includes actual measurement signals associated with a measurement of each of a plurality of instances of the current version of the semiconductor structure in a prior process state, and corresponding measured values of the parameter of interest associated with a reference measurement of each of the plurality of instances of the current version of the semiconductor structure by a reference metrology system.

In some embodiments, a training data set includes assumed values of a parameter of interest characterizing the current version of the semiconductor structure in a prior process state, and synthetically generated measurement signals corresponding to each of the assumed values of a parameter of interest.

In general, the training data set may include actual and synthetically generated measurement signals and corresponding values of one or more parameters of interest associated with the structure of interest.

In a further aspect, the training set of measurement signals includes historical measurement signals generated by a measurement of a historical version of the structure by the metrology system. In general, a historical version of a structure differs from the present version of the structure in a design revision, a process recipe, or both. A version of a semiconductor structure indicates the design version of a semiconductor structure, a process recipe version employed to fabricate the semiconductor structure, or both. A current version of a semiconductor structure is the design revision, process recipe, or both, associated with semiconductor structure for which a present state measurement model is being trained. A historical version of the semiconductor structure is a different design revision, different process recipe, or both, associated with the semiconductor structure. Typically, a historical version of a semiconductor structure is an earlier design revision, earlier process recipe, or both, for which a significant amount of validated measurement data has been collected. In this manner, measurement data associated with historical versions of a semiconductor structure are typically trusted.

In some embodiments, a training data set includes actual measurement signals associated with a measurement of each of a plurality of instances of a historical version of the semiconductor structure in a present process state and a corresponding measured value of the parameter of interest, associated with a reference measurement of each of the plurality of instances of the historical version of the semiconductor structure in the present process state by a reference metrology system.

In some embodiments, a training data set includes actual measurement signals associated with a measurement of each of a plurality of instances of a historical version of the semiconductor structure in a prior process state and a corresponding measured value of the parameter of interest, associated with a reference measurement of each of the plurality of instances of the historical version of the semiconductor structure in the prior process state by a reference metrology system.

In general, the training data set may include historical measurement signals and corresponding values of one or more parameters of interest associated with the structure of interest.

In general, training data sets may include training data associated with historical, prior state measurements at any number of prior process steps. Each of the different prior states of the semiconductor process flow and the present state of the semiconductor process flow are separated by one or more intervening semiconductor manufacturing process steps. Furthermore, each of the different prior states of the semiconductor process flow and any other of the different prior states are separated by one or more intervening semiconductor manufacturing process steps.

In some examples, training data continues to be generated based on reliable, high-throughput, in-line measurements of a continuously growing number of instances of a structure of interest at a prior state, along with corresponding high-throughput, in-line measurement signals in the present state. In these examples, prior state and present state measurements continue to be collected from in-line, production wafers. Periodically, the expanded set of training data is employed to retrain the present state measurement model to continuously improve the accuracy and reliability of the trained present state measurement model as production continues.

In general, measurement functionality based on measurement signal combinations as described herein may be implemented on any number of different metrology systems, including, but not limited to, various X-ray based measurement modalities, such as X-ray scatterometry, X-ray reflectometry, X-ray diffraction, X-ray fluorescence, etc., various optically based measurement modalities, such as spectroscopic reflectometry, scatterometry, and ellipsometry, image based reflectometry, etc., and various electron beam based measurement modalities, such as model based electron beam metrology.

In general, the scattering response signals or scattering response images described herein refer to pixel intensity values at the detector plane or diffraction order intensity values. Diffraction order intensity values are not directly measured by a transmission based, X-ray scatterometry system, but are derived from measured pixel intensities at the detector plane. However, synthetically generated diffraction order intensities may be computed directly. In some embodiments, it is desirable to compute and mathematically operate on diffraction order intensities to reduce computational effort.

Measurements of semiconductor structures as described herein may be employed as part of a semiconductor fabrication process in a number of different ways. In some embodiments, measurement results are employed directly to control a fabrication process. In some examples, measured values of one or more parameters of interest, e.g., critical dimensions, are directly employed to control one or more process parameters, e.g., focus, dosage, etch time, etc.

In some embodiments, the structures under measurement include some amount of periodicity to scatter light in discernable discrete diffraction orders. Diffraction from structures exhibiting periodicity in two dimensions appears as discrete points on the image plane of the detector. Diffraction from structures exhibiting periodicity in one dimension appears as discrete points on a line in the image plane of the detector.

In some embodiments, the structures under measurement are quasi-periodic in one or both in-plane dimensions. In these embodiments, the diffraction images exhibit continuous lines of diffracted light.

In general, scatterometry based measurements as described herein may be employed to measure any semiconductor structure that exhibits periodicity or quasi-periodicity in one or both in-plane dimensions, e.g., the x-direction, the y-direction, or both.

Scatterometry based measurements, as described herein, may be performed using narrowband illumination light centered about any suitable illumination wavelength, e.g., narrowband illumination light centered about any wavelength suitable to transmit through the wafer and generate scattering from stacked structures. Although, in many measurement applications, the wavelength of illumination light is in the X-Ray range, in general, depending on the size of structures under measurement, the wavelength of illumination light may be in the optical range, including ultraviolet, visible, and infrared ranges. In preferred embodiments, the illumination light is narrow band with low beam divergence to reduce smearing of diffraction orders at the detector due to varying illumination wavelengths. Order separation on an X-Ray detector, specifically, is a function of wavelength, target periodicity, incidence angle, divergence angle of the uncollimated illumination light, detector resolution and distance from the target, etc. Nevertheless, in one dimension it is fundamentally governed by the diffraction equation, d*sin(Δθ)=λ, where d is the periodicity of the structure, λ is the illuminating wavelength and Δθ is the angular spacing between orders. From this equation or the two dimensional equivalent, a practitioner skilled in the art may quickly determine the bandwidth and beam divergence required to resolve the individual orders on a detector.

Although useful measurements may be performed at two different incidence angles, in general, measurement sensitivity is improved by collecting measurement data over a large, diverse data set. This is achieved by collecting measurement data over a longer period of time, over a larger range of different illumination incidence angles, over a smaller spacing between different illumination incidence angles, or any combination thereof.

It should be recognized that the various steps described throughout the present disclosure may be carried out by a single computer system 130 or, alternatively, a multiple computer system 130. Moreover, different subsystems of the system 100, such as the specimen positioning system 140, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

In addition, the computer system 130 may be communicatively coupled to the x-ray illumination source 110, beam shaping slit mechanism 120, specimen positioning system 140, and detector 119 in any manner known in the art. For example, the one or more computing systems 130 may be coupled to computing systems associated with the x-ray illumination source 110, beam shaping slit mechanism 120, specimen positioning system 140, and detector 119, respectively. In another example, any of the x-ray illumination source 110, beam shaping slit mechanism 120, specimen positioning system 140, and detector 119 may be controlled directly by a single computer system coupled to computer system 130.

The computer system 130 may be configured to receive and/or acquire data or information from the subsystems of the system (e.g., x-ray illumination source 110, beam shaping slit mechanism 120, specimen positioning system 140, detector 119, and the like) by a transmission medium that may include wireline and/or wireless portions. In this manner, the transmission medium may serve as a data link between the computer system 130 and other subsystems of the system 100.

Computer system 130 of the metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, or external systems). For example, the computing system 130 may be configured to receive measurement data (e.g., signals 135) from a storage medium (i.e., memory 132) via a data link. For instance, image results obtained using detector 119 may be stored in a permanent or semi-permanent memory device (e.g., memory 132). In this regard, the measurement results may be imported from on-board memory or from an external memory system. Moreover, the computer system 130 may send data to other systems via a transmission medium.

Computing system 130 may include, but is not limited to, a personal computer system, mainframe computer system, cloud-based computing system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIG. 1, program instructions stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

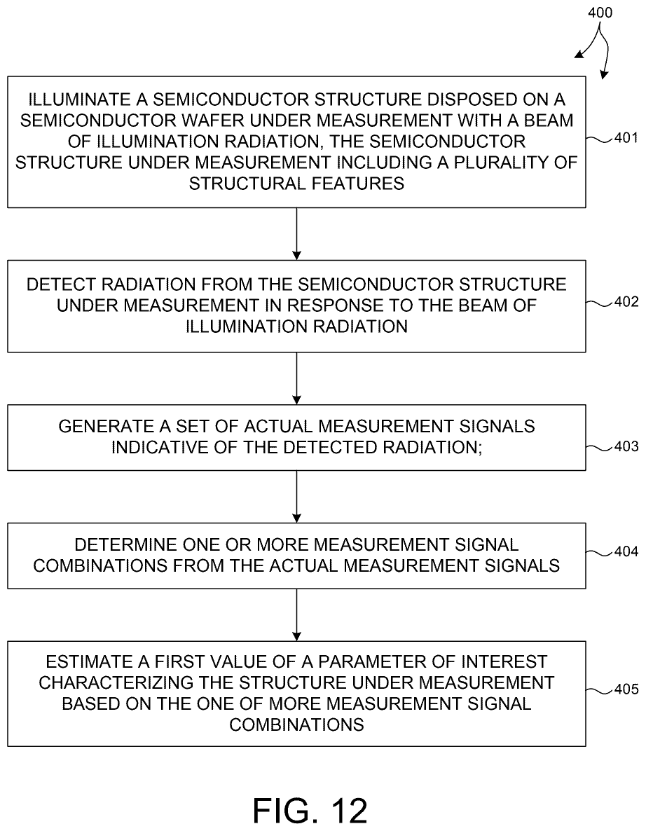

FIG. 12 illustrates a method 400 suitable for implementation by the metrology systems 100 and 300 of the present invention. In one aspect, it is recognized that data processing blocks of method 400 may be carried out via a pre-programmed algorithm executed by one or more processors of computing systems 130 and 316. While the following description is presented in the context of metrology systems 100 and 300, it is recognized herein that the particular structural aspects of metrology systems 100 and 300 do not represent limitations and should be interpreted as illustrative only.

In block 401, a semiconductor structure disposed on a semiconductor wafer under measurement is illuminated with a beam of illumination radiation. The semiconductor structure under measurement includes a plurality of structural features.

In block 402, radiation is detected from the semiconductor structure under measurement in response to the beam of illumination radiation.

In block 403, a set of actual measurement signals indicative of the detected radiation is generated.

In block 404, one of more measurement signal combinations are determined from the actual measurement signals.

In block 405, a first value of a parameter of interest is estimated based on the one or more measurement signal combinations. The parameter of interest characterizes the structure under measurement.

In some embodiments, measurements as described herein are implemented as part of a fabrication process tool. Examples of fabrication process tools include, but are not limited to, lithographic exposure tools, film deposition tools, implant tools, and etch tools. In this manner, the measurement results are used to control a fabrication process. In one example, T-SAXS measurement data collected from one or more targets is sent to a fabrication process tool. The T-SAXS measurement data is analyzed as described herein and the results used to monitor, and when necessary, adjust, the operation of the fabrication process tool.

Scatterometry measurements as described herein may be used to determine characteristics of a variety of semiconductor structures. Exemplary structures include, but are not limited to, FinFETs, low-dimensional structures such as nanowires or graphene, sub 10 nm structures, lithographic structures, through substrate vias (TSVs), memory structures such as DRAM, DRAM 4F2, FLASH, MRAM and high aspect ratio memory structures. Exemplary structural characteristics include, but are not limited to, geometric parameters such as line edge roughness, line width roughness, pore size, pore density, side wall angle, profile, critical dimension, pitch, thickness, overlay, and material parameters such as electron density, composition, grain structure, morphology, stress, strain, and elemental identification. In some embodiments, the metrology target is a periodic structure. In some other embodiments, the metrology target is aperiodic.

In some examples, measurements of critical dimensions, thicknesses, overlay, and material properties of stacked ratio semiconductor structures including, but not limited to, spin transfer torque random access memory (STT-RAM), three dimensional NAND memory (3D-NAND) or vertical NAND memory (V-NAND), dynamic random access memory (DRAM), three dimensional FLASH memory (3D-FLASH), resistive random access memory (Re-RAM), and phase change random access memory (PC-RAM) are performed with T-SAXS measurement systems as described herein.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including critical dimension applications and overlay metrology applications. However, such terms of art do not limit the scope of the term “metrology system” as described herein. In addition, the metrology systems described herein may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the measurement techniques described herein.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, XRF disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an illumination source configured to generate a beam of radiation incident on a semiconductor structure disposed on a semiconductor wafer under measurement, the semiconductor structure under measurement including a plurality of structural features;
a detector configured to detect radiation from the semiconductor structure under measurement in response to the incident beam of radiation and generate a set of actual measurement signals indicative of the detected radiation; and
a computing system configured to:
determine one or more measurement signal combinations from the actual measurement signals; and
estimate a first value of a parameter of interest characterizing the structure under measurement based on the one of more measurement signal combinations.

2. The metrology system of claim 1, wherein the estimating of the first value of the parameter of interest involves a trained measurement signal combination (MSC) based measurement model of the structure under measurement operating on the one or more measurement signal combinations.

3. The metrology system of claim 1, wherein the actual measurement signals are indicative of a measured response of the plurality of structural features of the semiconductor structure to measurements by the metrology system at a plurality of different values of one or more metrology system parameters, and wherein the one or more measurement signal combinations includes measurement signal information associated with the measurements by the metrology system at a plurality of different values of one or more metrology system parameters.

4. The metrology system of claim 1, wherein the determining of the one or more measurement signal combinations from the set of actual measurement signals involves an operation of a mathematical function or combination of multiple mathematical functions on the set of actual measurement signals associated with measurements of the structure of interest.

5. The metrology system of claim 1, wherein the determining of the one or more measurement signal combinations from the set of actual measurement signals involves tokenizing the set of actual measurement signals to generate a set of tokenized, actual measurement signals, and operating on the tokenized, actual measurement signals with a Measurement Signal Object (MSO) model.

6. The metrology system of claim 5, the computing system further configured to train the MSO model using a transformer employing an attention mechanism operating on a tokenized set of training measurement signals associated with a set of measurements at different values of one or more independent measurement system parameters and corresponding values of one or more parameters of interest.

7. The metrology system of claim 1, wherein the estimating of the first value of the parameter of interest is also based on the actual measurement signals.

8. The metrology system of claim 1, wherein the estimating of the first value of the parameter of interest involves a model based regression on the one of more measurement signal combinations.

9. The metrology system of claim 8, the computing system further configured to:
estimate a second value of the parameter of interest, wherein the estimating of the second value involves the trained measurement model of the structure under measurement operating on the one or more measurement signal combinations, wherein the second value of the parameter of interest is employed as a seed value in the model based regression on the one or more measurement signal combinations.

10. The metrology system of claim 8, the computing system further configured to:
estimate a second value of the parameter of interest, wherein the estimating of the second value involves the trained measurement model of the structure under measurement operating on the one or more measurement signal combinations, wherein the second value of the parameter of interest is employed to regularize the model based regression on the one or more measurement signal combinations.

11. The metrology system of claim 1, wherein the estimating of the first value of the parameter of interest involves a trained measurement model of the structure under measurement operating on the actual measurement signals, and wherein the one or more measurement signal combinations are provided as a conditional input to the trained measurement model.

12. The metrology system of claim 2, the computing system further configured to:
estimate a second value of the parameter of interest, wherein the estimating of the second value involves a model based regression on the actual measurement signals, wherein the second value of the parameter of interest is provided as a conditional input to the trained measurement model.

13. The metrology system of claim 2, the computing system further configured to:
train the MSC measurement model, wherein a training set of measurement signals includes synthetic measurement signals generated by a measurement model evaluated at a range of values of one or more material parameters, each of the one or more material parameters characterizing a material of the structure under measurement.

14. The metrology system of claim 13, wherein the training set of measurement signals includes measurement signals generated by a measurement of the semiconductor structure at a prior process state.

15. The metrology system of claim 13, wherein the training set of measurement signals includes historical measurement signals, wherein the historical measurement signals are indicative of a measurement response of a historical version of the structural features of the semiconductor structure to measurement by the metrology system.

16. The metrology system of claim 2, wherein the trained measurement model is a machine learning based measurement model or a library based measurement model.

17. The metrology system of claim 1, wherein the amount of radiation includes electron radiation, electromagnetic radiation in an x-ray range, electromagnetic radiation in an optical range, or any combination thereof.

18. A method comprising:
illuminating a semiconductor structure disposed on a semiconductor wafer under measurement with a beam of illumination radiation, the semiconductor structure under measurement including a plurality of structural features;
detecting radiation from the semiconductor structure under measurement in response to the beam of illumination radiation;
generating a set of actual measurement signals indicative of the detected radiation;
determining one or more measurement signal combinations from the actual measurement signals; and
estimating a first value of a parameter of interest characterizing the structure under measurement based on the one of more measurement signal combinations.

19. The method of claim 18, wherein the estimating of the first value of the parameter of interest involves a trained measurement signal combination (MSC) based measurement model of the structure under measurement operating on the one or more measurement signal combinations.

20. A metrology system comprising:
an illumination source configured to generate a beam of radiation incident on a semiconductor structure disposed on a semiconductor wafer under measurement, the semiconductor structure under measurement including a plurality of structural features;
a detector configured to detect radiation from the semiconductor structure under measurement in response to the incident beam of radiation and generate a set of actual measurement signals indicative of the detected radiation; and
a non-transitory, computer-readable medium comprising instructions that when executed by one or more processors causes the one or more processors to:
determine one or more measurement signal combinations from the actual measurement signals; and
estimate a first value of a parameter of interest characterizing the structure under measurement based on the one of more measurement signal combinations.
